(19) United States
(12) Patent Application Publication
(10) Pub. No.: US 2013/0000706 A1
(43) Pub. Date: Jan. 3, 2013

(54) TANDEM SOLAR CELL WITH IMPROVED TUNNEL JUNCTION

(75) Inventors: AHMED ABOU-KANDIL, ELMSFORD, NY (US); KEITH E. FOGEL, HOPEWELL JUNCTION, NY (US); AUGUSTIN J. HONG, WHITE PLAINS, NY (US); JEEHWAN KIM, LOS ANGELES, CA (US); DEVENDRA K. SADANA, PLEASANTVILLE, NY (US)

(73) Assignee: INTERNATIONAL BUSINESS MACHINES CORPORATION, ARMONK, NY (US)

(21) Appl. No.: 13/613,041

(22) Filed: Sep. 13, 2012

Related U.S. Application Data
(63) Continuation of application No. 13/161,081, filed on Jun. 15, 2011.

(51) Int. Cl. H01L 31/06; H01L 31/0376

(52) U.S. Cl. 136/255; 136/252; 136/258

(57) ABSTRACT

A photovoltaic device and method for fabricating a photovoltaic device include forming a light-absorbing semiconductor structure on a transmissive substrate including a first doped layer and forming an intrinsic layer on the first doped layer, wherein the intrinsic layer includes an amorphous material. The intrinsic layer is treated with a plasma to form seed sites. A first tunnel junction layer is formed on the intrinsic layer by growing microcrystals from the seed sites.

### RELATED APPLICATION DATA

This application is a Continuation application of co-pending U.S. patent application Ser. No. 13/161,081 filed on Jun. 15, 2011, incorporated herein by reference in its entirety.

### BACKGROUND

1. Technical Field

The present invention relates to photovoltaic devices, and more particularly to a device and method for improving performance through improved tunnel junction formation.

2. Description of the Related Art

Solar devices employ photovoltaic cells to generate current flow. Photons in sunlight hit a solar cell or panel and are absorbed by semiconducting materials, such as silicon. Carriers gain energy allowing them to flow through the material to produce electricity. Therefore, the solar cell converts the solar energy into a usable amount of electricity.

When a photon hits a piece of silicon, the photon may be transmitted through the silicon, the photon can reflect off the surface, or the photon can be absorbed by the silicon, if the photon energy is higher than the silicon band gap value. This generates an electron-hole pair and sometimes heat, depending on the band structure.

When a photon is absorbed, its energy is given to a carrier in a crystal lattice. Electrons in the valence band may be excited into the conduction band, where they are free to move within the semiconductor. The bond that the electron(s) were a part of form a hole. These holes can move through the lattice creating mobile electron-hole pairs.

A photon need only have greater energy than that of a band gap to excite an electron from the valence band into the conduction band. Since solar radiation is composed of photons with energies greater than the band gap of silicon, the higher energy photons will be absorbed by the solar cell, with some of the energy (above the band gap) being turned into heat rather than into usable electrical energy.

To enhance efficiency of solar cells, multi junction cells have been developed. Multi junction cells include two or more cells stacked on top of each other. Any radiation transmitted through a top cell has a chance of being absorbed by a lower cell. Solar cells may include thin film silicon structures with one or more tunnel junctions. In multi junction cells, multiple junctions are stacked creating the need to grow junction materials on top of one another. In the case of employing silicon materials, tunnel junctions for tandem cells could benefit from a lower resistance phase of silicon. However, the formation of an ultra-thin microcrystalline phase on an amorphous phase template is extremely challenging. Designs employing the microcrystalline phase on the amorphous phase often result in reduced cell efficiency due to the failure of crystallization.

### SUMMARY

A photovoltaic device and method for fabricating a photovoltaic device include forming a light-absorbing semiconductor structure on a transmissive substrate including a first doped layer and forming an intrinsic layer on the first doped layer, wherein the intrinsic layer includes an amorphous material. The intrinsic layer is treated with plasma to form seed sites. A first tunnel junction layer is formed on the intrinsic layer by growing microcrystals from the seed sites.

A method for fabricating a photovoltaic device includes forming a first photovoltaic cell by: forming a transparent conductor on a transmissive substrate; forming a first doped layer on the transparent conductor; forming an intrinsic layer on the first doped layer, wherein the intrinsic layer includes an amorphous material; treating the intrinsic layer with a plasma to form seed sites; forming a first tunnel junction layer on the intrinsic layer by growing microcrystals from the seed sites; and forming a second photovoltaic cell by: forming a second tunnel junction layer having an opposite polarity from the first tunnel junction layer, a corresponding intrinsic layer formed from a material having a different band gap from the first cell and a second doped layer formed on the corresponding intrinsic layer.

A photovoltaic device includes a light-absorbing semiconductor structure including a first doped layer, an intrinsic layer and a first tunnel junction layer, the intrinsic layer including an amorphous material phase. An interface between the intrinsic layer and the first tunnel junction layer includes a seed layer to enable microcrystalline growth of the first tunnel junction layer and a second first tunnel junction layer.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a photovoltaic device in accordance with one illustrative embodiment;

FIG. 2A is a cross-sectional view of a partially fabricated photovoltaic device showing a transparent conductive oxide formed on a substrate in accordance with one illustrative embodiment;

FIG. 2B is a cross-sectional view of the partially fabricated photovoltaic device of FIG. 2A showing a first doped layer formed in accordance with one illustrative embodiment;

FIG. 2C is a cross-sectional view of the partially fabricated photovoltaic device of FIG. 2B showing an amorphous intrinsic layer formed on the first doped layer and being treated by a plasma to form seed sites in accordance with one illustrative embodiment;

FIG. 2D is a cross-sectional view of the partially fabricated photovoltaic device of FIG. 2C showing a second doped layer (tunnel junction) formed on a seed layer of the amorphous intrinsic layer in accordance with one illustrative embodiment;

FIG. 2E is a cross-sectional view of the partially fabricated photovoltaic device of FIG. 2D showing another intrinsic layer formed on a third doped layer (tunnel junction) in accordance with one illustrative embodiment;

FIG. 3A is a bar chart showing cell performance (in percent efficiency) versus H⁺ treatment time (in seconds) of a tunnel junction of a cell in accordance with the present principles;

FIG. 3B is a bar chart showing cell performance (using fill factor) versus H⁺ treatment time (in seconds) of a tunnel junction of a cell in accordance with the present principles;

FIG. 3C shows plots of current density versus voltage for different H₂ plasma treatment times and doping rates in accordance with the present principles; and

FIG. 4 is a block/flow diagram showing a method for fabricating a photovoltaic device in accordance with the present principles.

### DETAILED DESCRIPTION OF PREFERRED EMBODIMENTS

A multi junction photovoltaic device having an improved fill factor is provided. The photovoltaic device may be employed as a solar cell. In addition, methods for forming a photovoltaic device with an improved fill factor are disclosed. The photovoltaic device includes one or more micro-crystalline silicon phase tunnel junctions formed in contact with an amorphous silicon template or intrinsic layer. Hydrogen content is a factor for crystalline phase formation on amorphous silicon. In accordance with one embodiment, a hydrogen (H₂) plasma treatment of a hydrogenated amorphous silicon template (e.g., a-Si:H) assists in creating crystalline seeds so that doping activation at a doped tunnel junction increases resulting in high conductivity. This reduces impedance at tunnel junctions in tandem solar cell structures. The crystalline seeds are then able to provide for further crystalline growth to faun a micro-crystalline layer on the amorphous silicon.

It is to be understood that the present invention will be described in terms of a given illustrative architecture for a solar cell; however, other architectures, structures, substrate materials and process features and steps may be varied within the scope of the present invention. Solar cell designs or chips including such designs may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

In the following description, numerous specific details are set forth, such as particular structures, components, materials, dimensions, processing steps and techniques to provide a thorough understanding of the present principles. However, it will be appreciated by one of ordinary skill in the art that these specific details are illustrative and should not be construed as limiting.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Methods as described herein may be used in the fabrication of integrated circuit chips and/or solar cells. The resulting integrated circuit chips or cells can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes photovoltaic devices, integrated circuit chips with solar cells, ranging from toys, calculators, solar collectors and other low-end applications to advanced products.

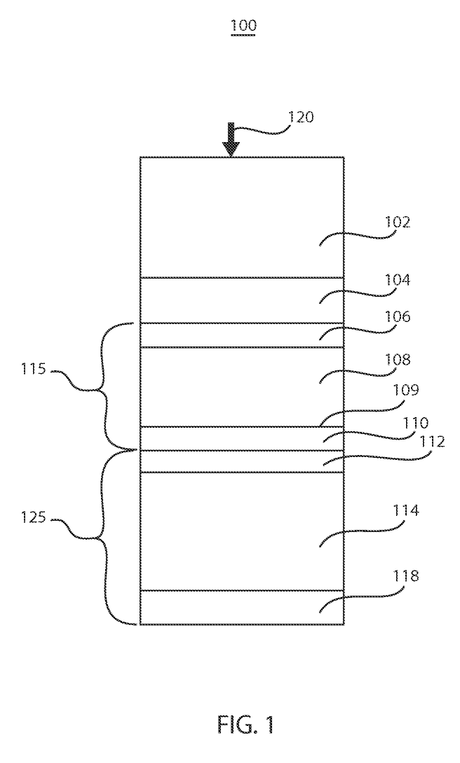

Referring now to the drawings in which like numerals represent the same or similar elements and initially to FIG. 1, an illustrative photovoltaic structure 100 is illustratively depicted in accordance with one embodiment. The photovoltaic structure 100 may be employed in solar cells, light sensors or other photovoltaic applications. Structure 100 includes a substrate 102 that permits a high transmittance of light. The substrate 102 may include a transparent material, such as glass, a polymer, etc. or combinations thereof.

A first electrode 104 includes a transparent conductive material. Electrode 104 may include a doped layer, e.g., an N-type dopant layer or a P-type dopant layer. Electrode 104 may include a transparent conductive oxide (TCO), such as, e.g., a fluorine-doped tin oxide (SnO₂:F, or “FTO”), doped zinc oxide (e.g., ZnO:Al), indium tin oxide (ITO) or other suitable materials. For the present example, a doped zinc oxide is illustratively employed for electrode 104. The TCO 104 permits light to pass through to an active light-absorbing material beneath and allows conduction to transport photo-generated charge carriers away from that light-absorbing material.

The light-absorbing material includes a doped layer 106 (e.g., a doped amorphous silicon (a-Si) or microcrystalline silicon (μc-Si) layer, and in particular a P-type doped layer). In this illustrative structure 100, layer 106 is formed on electrode 104. An intrinsic layer 108 of compatible material is formed on layer 106. Intrinsic layer 108 may be undoped and may include an amorphous silicon material. The intrinsic layer 108 may include a thickness of between about 100-300 nm, although other thicknesses are contemplated. A seed layer 109 is formed on the amorphous silicon of the intrinsic layer 108. The seed layer 109 is formed by bombarding a surface of the intrinsic layer 108 with plasma, e.g., H₂ plasma. The plasma causes silicon seeds to begin to form on a surface of layer 108.

The intrinsic layer 108 is preferably a thin film hydrogenated amorphous silicon (a-Si:H) or a hydrogenated amorphous silicon carbide (a-SiC:H) which may be deposited by a chemical vapor deposition (CVD) process, or a plasma-enhanced (PE-CVD)) from silane gas and hydrogen gas.

In this embodiment, a second doped layer 110 (e.g., an N-type layer) is formed on the intrinsic layer 108 as an N-type tunnel junction. Intrinsic layer 108 may include an amorphous hydrogenated silicon (a-Si:H), and layer 110 preferably includes an N-type hydrogenated microcrystalline (μc-Si:H). The layer 110 is grown from the seed layer 109. The seed layer 109 is formed by the hydrogen plasma treatment on the amorphous silicon of the intrinsic layer 108. The plasma activates the surface so that a thin tunnel junction 110 can subsequently be grown as microcrystalline silicon. The layer 110 may include an ultra-thin thickness, e.g., between about 0.1 nm to about 20 nm and more preferably less than about 5 nm. To promote conductivity of the tunnel junction 110, more doping may be provided in the region.

To increase the performance of the device 100, it is desirable that any radiation that passes through a top cell 115 is absorbed in a lower cell(s) 125. This is achieved by providing energy gap splitting (E_{g} splitting). For example, the top cell 115 has higher band gap materials and receives light 120 first. The light spectra that are not absorbed at the top cell 115 enter the cell 125. A larger band gap difference between two different junctions is better to prevent the light spectra from being shared between the junctions. This is to maximize photocurrent. Energy gap splitting permits the absorption of radiation with different energies between the cells. Since the band gap of the top cell 115 is maintained at a higher level, the lower level cell(s) 125 is/are designed to have a lower band gap. In this way, the lower cells have a higher probability of absorbing transmitted radiation, and the entire multi junction cell becomes more efficient since there are fewer photon energy levels shared between the layered cells. This results in an increased probability of absorbing light passing through to the bottom cell 125 hence increasing the current in the lower cells 125 and increasing short circuit current, J_{SC}.

To increase efficiency, it is preferable that a greater difference between band gaps exists between the top cell 115 (higher band gap), and the bottom cell 125 (lower band gap) by keeping an absolute high level of band gap energy (E_{g}) for all cells to maintain high open circuit voltage, Voc.

The bottom cell 125 in the present embodiment includes a doped layer 112 (e.g., P-type), which is formed on the N-type layer 110 as a P-type tunnel junction. The layer 112 preferably includes a P-type hydrogenated microcrystalline silicon (μc-Si:H). The layer 112 may be grown on the layer 110 or may be grown in a continuous process with layer 110, switching the dopant types during the deposition process to form both layers 110 and 112. The layer 112 may include an ultra-thin thickness, e.g., of between about 0.1 nm to about 20 nm and more preferably less than about 5 nm. An intrinsic layer 114 of compatible material is formed on layer 112.

With the microcrystalline structure provided for tunnel junction layers 110 and 112, the active doping concentration can effectively be increased by one or two orders of magnitude compared with a doping capacity of an amorphous phase, thus increasing conductivity and overall cell efficiency. Intrinsic layer 114 may be undoped and may include a hydrogenated microcrystalline silicon (μc-Si:H) or a hydrogenated amorphous silicon germanium (e.g., a-SiGe:H) material or other suitable material. The intrinsic layer 114 may include a thickness of about 150 nm, although other thicknesses are contemplated.

The silicon germanium layer 114 may be deposited by a chemical vapor deposition (CVD) process or a plasma-enhanced (PE-CVD)) to form amorphous silicon germanium. In this embodiment, an N-type layer 118 is formed on the intrinsic layer 114. Layer 118 preferably includes an N-type amorphous or microcrystalline silicon. If additional tandem cells are to be added, layer 118 may include μc-Si:H formed using another seed layer as described above. The layer 118 may include an ultra-thin thickness, e.g., less than about 20 nm and more preferably less than about 5 nm. Additional cells and/or layers (e.g., reflectors, etc.) may be formed after cell 125 is completed. In particularly useful embodiments, top cell 115 may include a-Si:H or a-SiC:H and the bottom cell 125 may include a-SiGe:H and μc-Si:H. It should be noted that the tandem cells may include the same materials or other materials from those presented. For example, the cell 125 may include the same materials as cell 115 or include CIGS (CuInGaS), Cu₂ZnSn(S, Se)₄ (CZTS or CZTSe), etc.

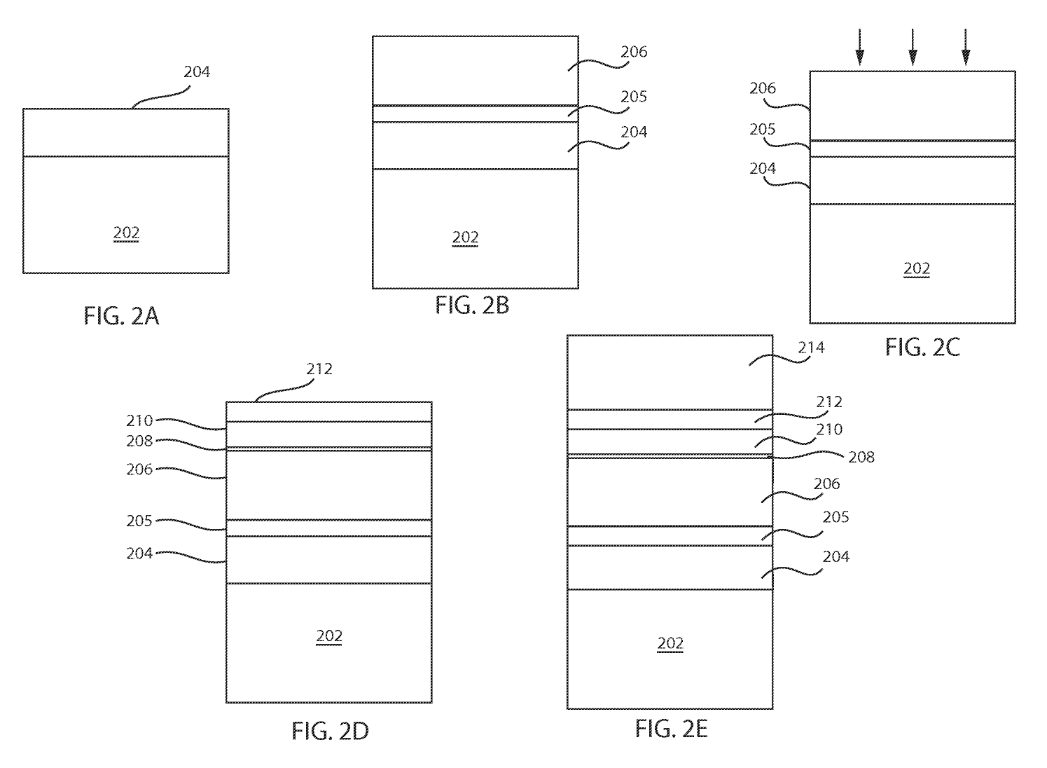

Referring to FIGS. 2A-2E, an illustrative processing sequence is shown for providing a photovoltaic device in accordance with the present principles. FIG. 2A shows a substrate 202, e.g., a transparent substrate, having a transparent conductor 204 formed thereon. Substrate 202 may include glass, a polymer, etc., and the transparent conductor may include, ZnO:Al, ITO, etc.

In FIG. 2B, a doped layer 205 is formed on the transparent electrode 204 and may include amorphous Si and/or amorphous SiC. An intrinsic layer 206 is formed on doped layer 205. Intrinsic layer 206 preferably includes an amorphous silicon layer formed on doped layer 205.

In FIG. 2C, intrinsic layer 206 is treated with plasma to form seeds for microcrystalline growth. The plasma preferably includes an H₂ plasma shower. In one illustrative embodiment, the H₂ plasma shower is performed at between about 150 degrees C. and 250 degrees C. The H₂ plasma shower is performed with a pressure between about 0.1 to about 10 Torr and a power of between about 30 to about 3000 mW/cm² for about 60 sec to about 1000 sec. The plasma shower results in the formation of a seed layer 208 depicted in FIG. 2D.

In FIG. 2D, tunnel junction layers 210 and 212 are formed on seed layer 208. Layer 210 may be formed using CVD or PECVD deposition processes. The deposition process may include, e.g., N-type dopants for layer 210 and P-type dopants for layer 212. In one embodiment, both layers are formed in a same chamber during a same process in which the type of dopants is switched during the process. Alternately, the layers 210 and 212 are formed separately. Tunnel junction layers 210 and 212 are preferably microcrystalline silicon. Doping efficiency is increased by making microcrystalline silicon tunnel junctions on the seed layer 208 resulting in improved fill factor (FF) by reducing impedance at the tunnel junctions.

In FIG. 2E, another intrinsic layer 214 is formed on layer 212. The intrinsic layer 214 may include SiGe, microcrystalline silicon, or other suitable materials. Processing continues to complete the cell (e.g., forming another doped layer (not shown), etc.). Additional cells may be provided which may or may not include an amorphous to microcrystalline silicon interface in accordance with the present principles.

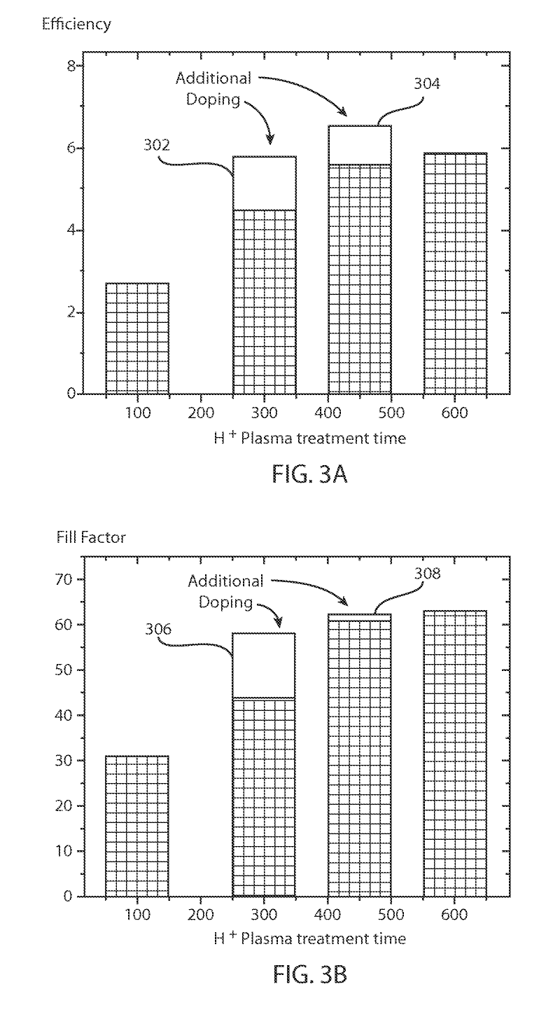

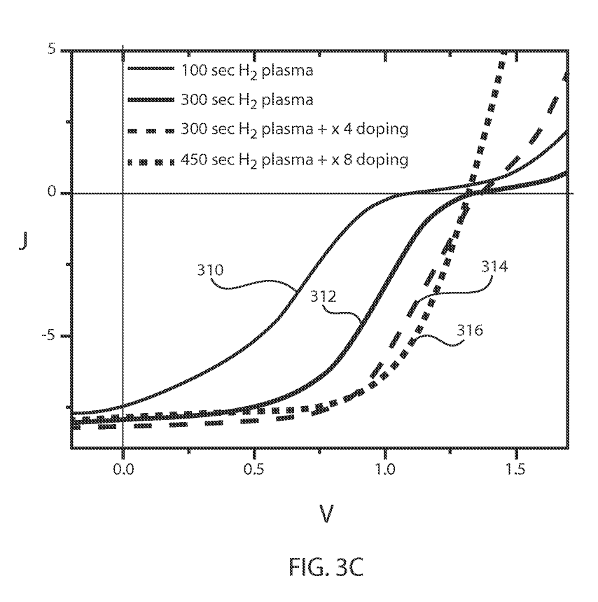

Referring to FIG. 3A, cell performance (in percent efficiency) versus H⁺ treatment time (in seconds) of a tunnel junction of a cell is illustratively shown. As indicated, cell efficiency is increased with the amount of time the H+ plasma treatment is conducted. Additional doping in the tunnel junction region also increases the efficiency as shown by regions 302 and 304.

Referring to FIG. 3B, cell performance (fill factor) versus H⁺ treatment time (in seconds) of a tunnel junction of a cell is illustratively shown. As indicated, fill factor is increased with the amount of time the H+ plasma treatment is conducted. Additional doping in the tunnel junction region also increases the fill factor as shown by regions 306 and 308. Fill factor (FF) is a ratio of the maximum power point (Pₘ) divided by open circuit voltage (V_{oc}) and short circuit current

$$( {J}_{sc} ) \text{:} FF = \frac{{P}_{m}}{{V}_{oc} {J}_{sc}} .$$

The fill factor indicates efficiency of photovoltaic devices in the current energy environment.

Referring to FIG. 3C, current density (J) is plotted versus voltage (V) for a solar cell structure formed with different hydrogen plasma conditions. Tandem cells with different deposition conditions for tunnel junctions show that increased H⁺ treatment helps promote crystallinity in tunnel junctions and increased doping enhances conductivity of tunnel junctions which appears in J-V curves by reduced humps at V=0. This results in improved FF.

The above-mentioned trend is systematically shown in the plots 310-316. Plot 310 shows H₂ plasma treatment for 100 seconds. Plot 312 shows H₂ plasma treatment for 300 seconds. Plot 314 shows H₂ plasma treatment for 300 seconds with a 4 times increase in the dopant levels. Plot 316 shows H₂ plasma treatment for 450 seconds with 8 times the dopant levels. Overall, increased hydrogen plasma time and doping enhances fill factor of tandem solar cells. In this example, the base dopant level may be 1-5% Standard Cubic Centimeters per Minute (sccm) of dopant gas in Silane. It should be understood that other increases in dopant levels can be achieved using other techniques and gases.

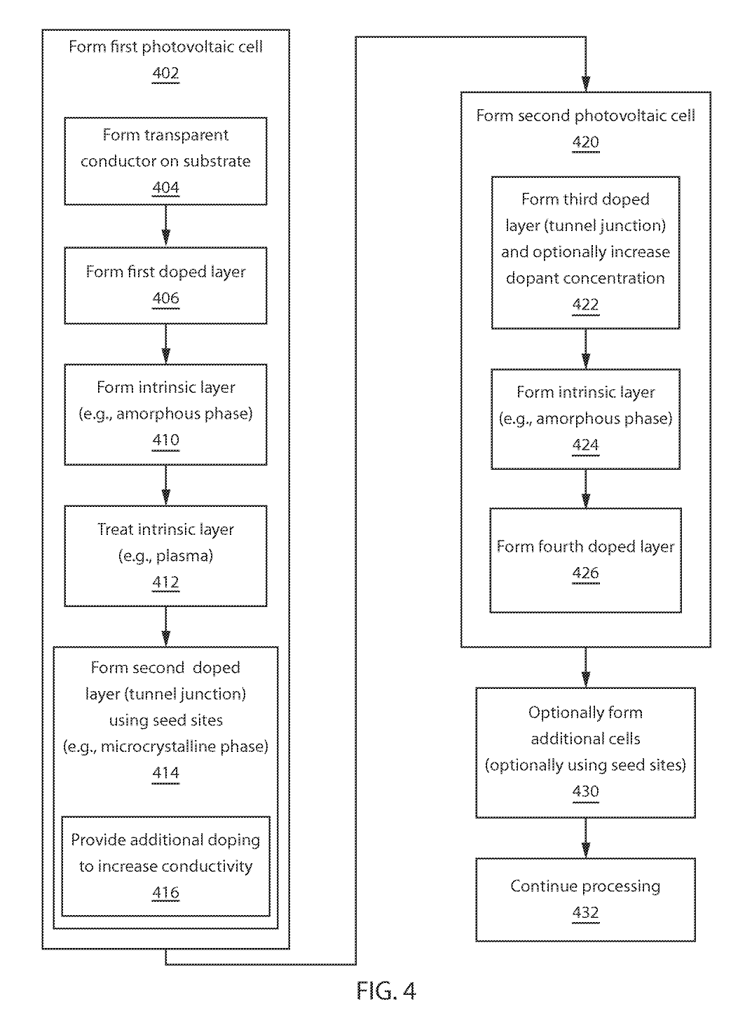

Referring to FIG. 4, a block/flow diagram shows a method for fabricating a photovoltaic device in accordance with one illustrative embodiment. In block 402, a first photovoltaic cell or device is formed. The present method may include forming a single device or cell or may include forming a multi junction device with a plurality of stacked cells. In block 404, a transparent conductor is formed on a transmissive substrate. The conductor may include a zinc oxide, indium tin oxide, or other transparent conductors. In block 406, a first doped layer is formed. This may include depositing a doped material (e.g., amorphous silicon) on the transparent conductor.

In block 410, an intrinsic layer is formed on the first doped layer. The intrinsic layer preferably may include an amorphous material. In this case, forming an amorphous material on the first doped layer (which includes, e.g., another amorphous material) is not difficult. In block 412, the intrinsic layer is treated with a plasma to form seed sites. If the intrinsic layer is formed from amorphous silicon then the plasma preferably includes a hydrogen plasma. Other plasmas may also be employed. In addition, other techniques may be employed for forming seed sites, such as, e.g., annealing the intrinsic layer, etc.

In block 414, a second doped layer (a tunnel junction) is formed on the intrinsic layer by growing microcrystals from the seed sites. The microcrystals may include microcrystalline silicon. Other amorphous/microcrystalline combinations may also be employed, e.g., a-Ge/microcrystalline Ge, etc. The second doped layer may have its dopant concentration increased to improve conductivity and therefore overall cell efficiency in block 416. The microcrystalline phase supports greater dopant levels and therefore greater conductivity.

In block 420, a second photovoltaic cell may be formed. In block 422, a third doped layer (tunnel junction) having an opposite polarity from the second doped layer is formed. The second and third doped layers are tunnel junctions. The second and third doped layers are formed from crystalline material as enabled by the seed layer. The third doped layer may have its dopant concentration increased to improve conductivity as well. A corresponding intrinsic layer is preferably formed from a material having a different band gap from the first cell in block 424. The band gaps are preferably selected such that the band gap energy increases with depth (e.g., each cell further from incident light has increased band gap energy). The band gaps are selected to provide maximum collection efficiency (e.g., a band gap splitting arrangement). In block 426, a fourth doped layer is formed on the intrinsic layer of the second cell. Depending on material selection, a seed layer may be formed prior to the formation of the fourth doped layer.

In block 430, one or more additional light-absorbing semiconductor structures may be formed on the second photovoltaic cell to continue to stack tandem cells. This may or may not include the formation of seed sites as described above. The seed sites (plasma treatment) may be employed if additional cells are provided. Other structures may also be formed, e.g., back reflectors, etc. In block 432, processing continues to complete the device or system.

Having described preferred embodiments for tandem solar cell with an improved tunnel junction and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A photovoltaic device, comprising:
a light-absorbing semiconductor structure including a first doped layer, an intrinsic layer and a first tunnel junction layer, the intrinsic layer including an amorphous material phase; and
an interface between the intrinsic layer and the first tunnel junction layer including a seed layer to enable microcrystalline growth of the first tunnel junction layer and a second first tunnel junction layer.

2. The photovoltaic device as recited in claim 1, further comprising a transmissive substrate on which the semiconductor structure is formed.

3. The photovoltaic device as recited in claim 2, the transmissive substrate further comprising a transparent electrode.

4. The photovoltaic device as recited in claim 1, wherein the intrinsic layer includes amorphous silicon and the first and second tunnel junction layers include microcrystalline silicon.

5. The photovoltaic device as recited in claim 1, wherein the photovoltaic device is included in a stack of photovoltaic devices.

6. The photovoltaic device as recited in claim 5, wherein the stack of photovoltaic devices includes band gap splitting.

7. The photovoltaic device as recited in claim 1, wherein the first and second tunnel junction layers include ultra-thin doped layers each having a thickness of between about 0.1 nm and about 20 nm.

8. The photovoltaic device as recited in claim 1, wherein the first and second tunnel junction layers include a microcrystalline phase having additional dopants beyond a capability of an amorphous phase to improve conductivity.
